(19) United States
(12) Patent Application Publication
(10) Pub. No.: US 2026/0068204 A1
(43) Pub. Date: Mar. 5, 2026

(54) METHODS FOR FORMING SEMICONDUCTOR DEVICE HAVING NANOSHEET TRANSISTOR

(71) Applicant: TAIWAN SEMICONDUCTOR MANUFACTURING COMPANY, LTD., Hsinchu (TW)

(72) Inventors: Guan-Lin CHEN, Hsinchu (TW); Hsien-Chih HUANG, Hsinchu (TW); Kuo-Cheng CHIANG, Hsinchu (TW); Shi Ning JU, Hsinchu (TW); Chih-Hao WANG, Hsinchu (TW)

(21) Appl. No.: 18/987,090

(22) Filed: Dec. 19, 2024

Related U.S. Application Data
(60) Provisional application No. 63/690,560, filed on Sep. 4, 2024.

(51) Int. Cl. H10D 30/01; H10D 30/00; H10D 62/10; H10D 64/01

(52) U.S. Cl. CPC H10D 30/0196; H10D 30/509; H10D 62/116; H10D 64/017

(57) ABSTRACT

Various embodiments of the present disclosure provide a method for forming a semiconductor device structure. In one embodiment, the method includes forming a fin over a substrate, wherein the fin comprises first semiconductor layers and second semiconductor layers alternating stacked. The method also includes forming a sacrificial gate structure over the fin, removing portions of the fin not covered by the sacrificial gate structure, replacing the second semiconductor layers with a sacrificial dielectric material, recessing edge portions of the sacrificial dielectric material to form cavities between the first semiconductor layers, forming a dielectric spacer in the cavities by depositing a conformal layer of a dielectric liner layer on exposed surfaces of each cavity, forming source/drain features on opposite sides of the sacrificial gate structure, and replacing the sacrificial gate structure and the sacrificial dielectric material with a gate structure wrapping around the first semiconductor layers.

### CROSS-REFERENCE TO RELATED APPLICATIONS

This application claims priority to U.S. Provisional Application Ser. No. 63/690,560 filed on Sep. 4, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, it becomes an increasing challenge to reduce parasitic capacitance between source/drain features and gate while maintaining desired K value for the devices. Improved structures and methods for manufacturing the same are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure in accordance with some embodiments.

FIGS. 6, 7, 8, 9, 10, 11, 12, 13, 14, 16, 17, 18, 19, 20, 21, 22, 23, 24, and 25 are cross-sectional side views of various stages of manufacturing the semiconductor device structure taken along cross-section A-A of FIG. 5, in accordance with some embodiments.

FIG. 12-1 illustrates an enlarged view of a portion of the semiconductor device structure showing the oxide layers on the filling layers, in accordance with some embodiments.

FIG. 13-1 illustrates an enlarged view of a portion of the semiconductor device structure showing the air gap is formed after removal of the filling layers, in accordance with some embodiments.

FIG. 14-1 illustrates an enlarged view of a portion of the semiconductor device structure showing the dielectric liner layer, in accordance with some embodiments.

FIGS. 15A, 15B, and 15C are schematic views of the dielectric liner layer showing air gaps with different shapes, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

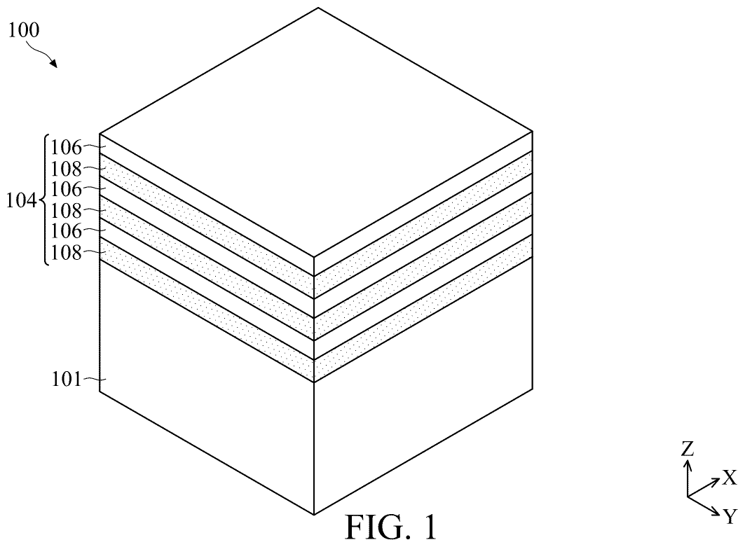

FIGS. 1 to 25 show non-limiting processes for manufacturing a semiconductor device structure 100 according to embodiments of the present disclosure. It is understood that additional operations can be provided before, during, and after processes shown by FIGS. 1 to 25, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100 in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 101 is made of silicon. The substrate 101 may be doped or un-doped. The substrate 101 may be a bulk semiconductor substrate, such as a bulk silicon substrate that is a wafer, a silicon-on-insulator (SOI) substrate, a multi-layered or gradient substrate, or the like.

The substrate 101 may include various regions that have been doped with impurities (e.g., dopants having p-type or n-type conductivity). Depending on circuit design, the dopants may be, for example phosphorus for n-well and/or an n-type field effect transistors (NFET) and boron for p-well and/or a p-type field effect transistors (PFET).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108 vertically stacked over the substrate 101. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GalnP, GalnAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

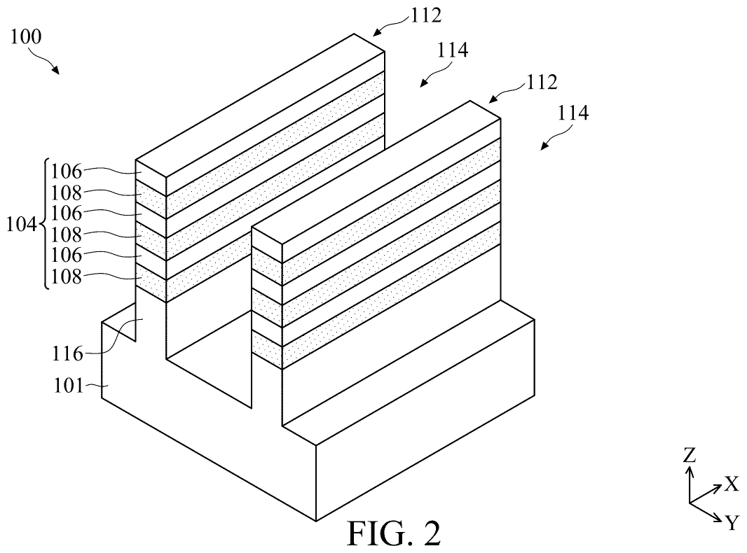

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

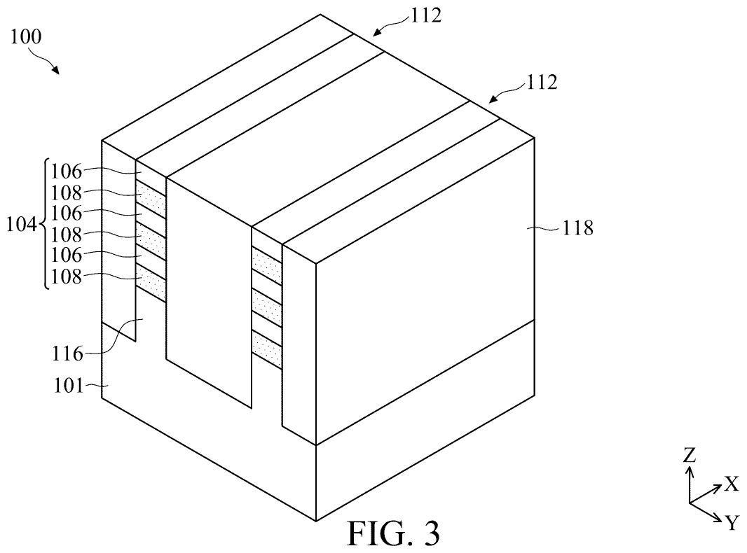

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SION), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

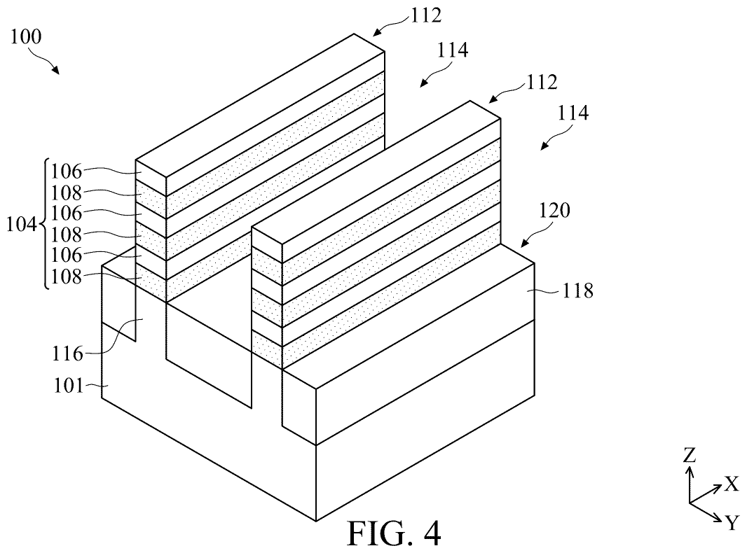

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or at a below a surface of the second semiconductor layers 108 in contact with the well portion 116 formed from the substrate 101.

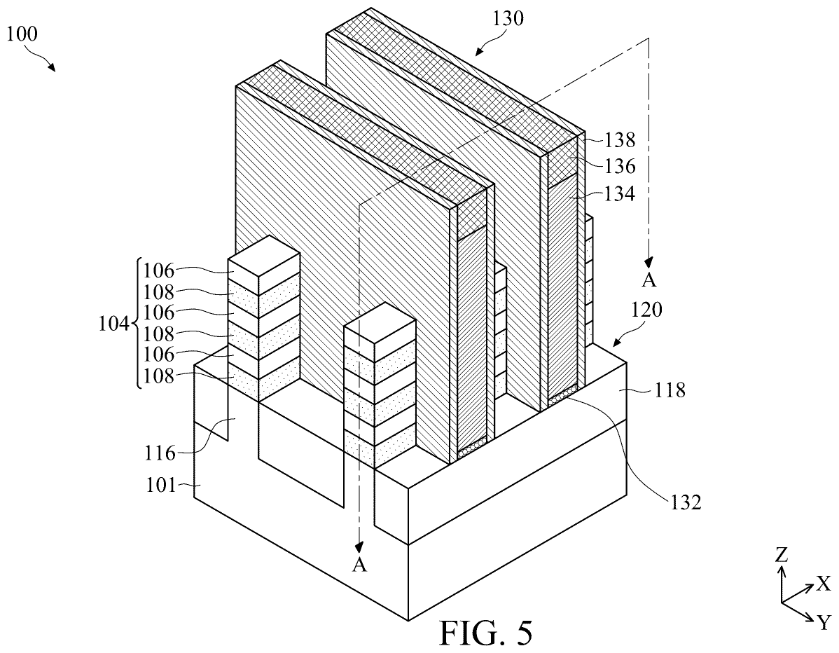

In FIG. 5, one or more sacrificial gate structures 130 (only two are shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While two sacrificial gate structures 130 are shown, three or more sacrificial gate structures 130 may be arranged along the X direction in some embodiments.

The sacrificial gate dielectric layer 132 may include one or more layers of dielectric material, such as silicon oxide (SiOₓ) or a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof. In some embodiments, the gate spacer 138 may be a dual-layer including a first dielectric layer 138a (e.g., SiO₂) and a second dielectric layer 138b (e.g., SiN).

The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various S/D regions may be connected together and implemented as multiple functional transistors. It should be understood that the source region and the drain region can be interchangeably used since the epitaxial features to be formed in these regions are substantially the same. Source/drain region(s) may refer to a source or a drain, individually or collectively dependent upon the context.

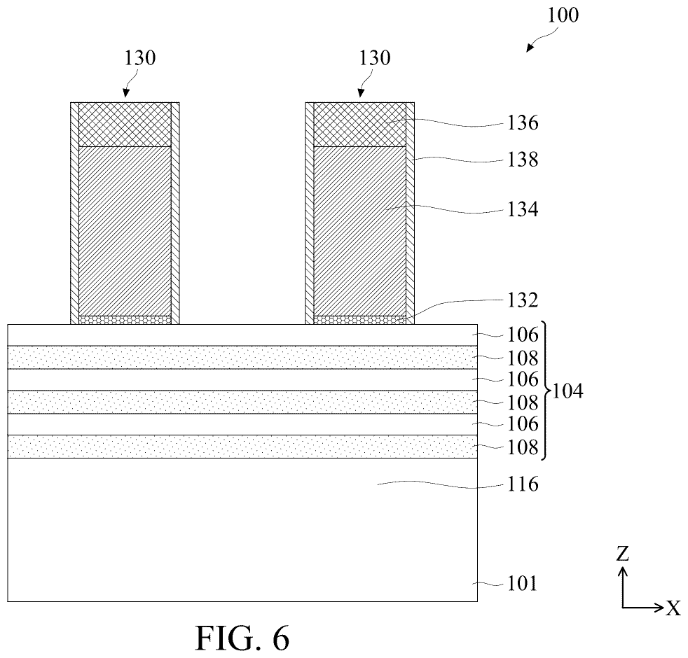

FIGS. 6-26 are cross-sectional side views of various stages of manufacturing the semiconductor device structure 100 taken along cross-section A-A of FIG. 5, in accordance with some embodiments. Cross-section A-A is in a plane of the fin structure 112 (FIG. 4) along the X direction.

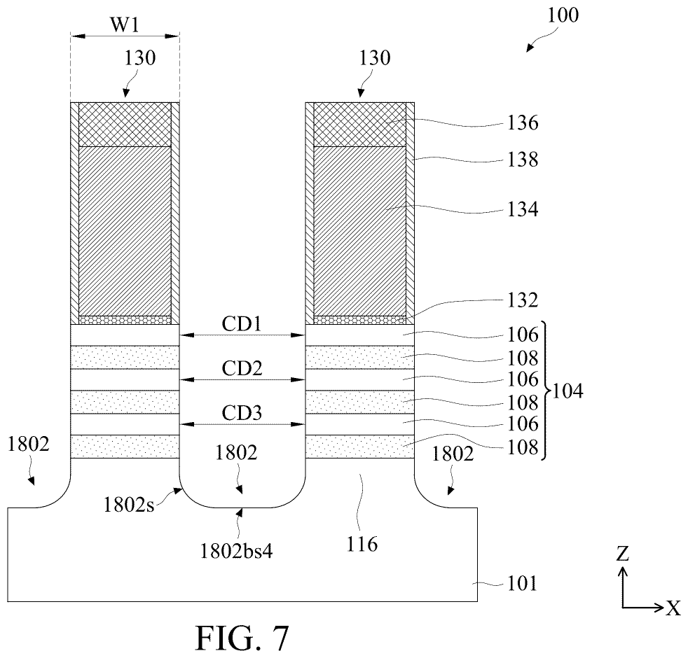

In FIG. 7, exposed portions of the fin structures 112 not covered by the sacrificial gate structures 130 and the gate spacers 138 are recessed to form source/drain (S/D) regions. The removal process may include one or more suitable etch processes, such as dry etch, wet etch, or a combination thereof. The portions of the fin structures 112 are removed to expose the sidewalls of the fin structures 112 (FIG. 4). In some embodiments, the removal process is performed so that the sidewalls of the bottommost second semiconductor layer 108 of each fin structure 112 are fully exposed. In some embodiments, the removal process is performed such that a top surface of the substrate is etched to have a curved profile (e.g., concave), such as the embodiment shown in FIG. 7.

In some embodiments, the first section of the trenches at or near the topmost first semiconductor layer 106 has a first CD (CD1), the second section of the trenches 1802 at or near the second highest first semiconductor layer 106 of the stack of semiconductor layers 104 has a second CD (CD2), and the third section of the trenches 1802 at or near the third highest first semiconductor layer 106 of the stack of semiconductor layers 104 has a third CD (CD3). In some embodiments, the CD1, the CD2, and the CD3 are substantially the same. Each of the first semiconductor layers 106 in the fin structure 112 may have a width W1 that is substantially identical to one another. In some embodiments where the gate pitch is about 40 nm to about 50 nm, the CD3 may be about 0 nm to about 1 nm greater than the width W1. In such cases, the dimension of the first semiconductor layers 106 is gradually increased along the direction away from the sacrificial gate dielectric layer 132.

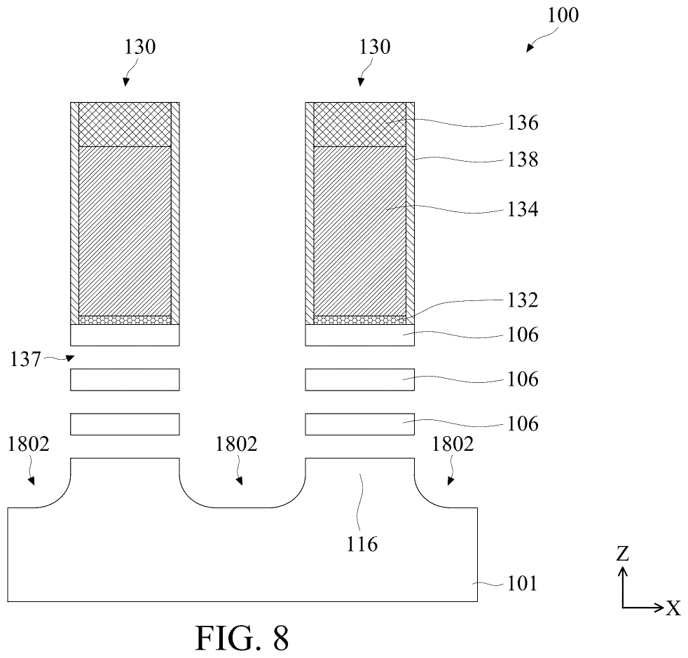

In FIG. 8, the second semiconductor layers 108 are removed. The removal of the second semiconductor layers 108 forms openings 137. The second semiconductor layers 108 may be removed by a selective etch process, such as a selective dry etch process, a selective wet etch process, or a combination thereof. The selective etch process does not substantially affect the gate spacers 138, the first semiconductor layers 106, the sacrificial gate electrode layers 130, and the substrate 101. In some embodiments, the selective etch process is a selective wet etching process. In cases where the second semiconductor layers 108 are made of SiGe and the first semiconductor layers 106 are made of silicon, the second semiconductor layer 108 can be selectively etched using an etchant such as, but not limited to, ammonium hydroxide (NH₄OH), tetramethylammonium hydroxide (TMAH), cthylenediamine pyrocatechol (EDP), or potassium hydroxide (KOH) solutions.

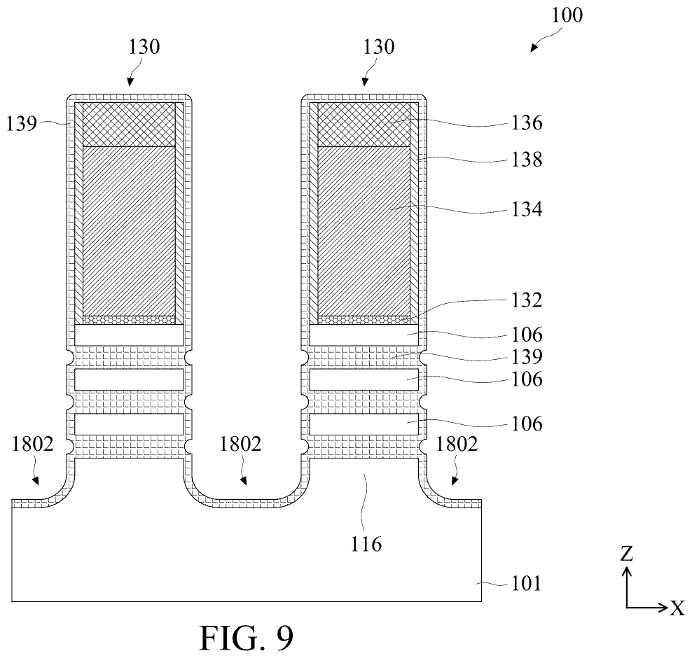

In FIG. 9, a sacrificial dielectric material 139 is formed in the openings 137 and on the exposed surfaces of the semiconductor device structure 100. In some embodiments, the sacrificial dielectric material 139 is an oxide formed by flowable chemical vapor deposition (FCVD) process. In some embodiments, the oxide is a carbon-containing silicon oxide. The use of the sacrificial dielectric material 139 helps to preserve surface profile of the first semiconductor layers 106 during the subsequent sheet (or channel) formation stage. In traditional cases where the second semiconductor layers 108 include Ge and the first semiconductor layers 106 include silicon, the Ge in the second semiconductor layers 108 may diffuse into and react with Si to form SiGe due to high temperature used during the formation of the subsequent epitaxial S/D features 146. When the second semiconductor layers 108 are selectively removed during the channel formation stage, a surface portion of the first semiconductor layers 106, which is now SiGe due to prior reaction with Ge, will also be removed. The removal of the second semiconductor layers 108 therefore induces extra silicon loss in the surface portion of the first semiconductor layers 106, resulting in thickness reduction and/or concave-like damage to the first semiconductor layers 106. When the thickness of silicon nanosheet channel layers (i.e., first semiconductor layers 106) is affected, the channel resistance (R_{ch}) of the nanosheet channel layers may increase and the ability of the nanosheet channel layers to conduct current flow (e.g., DC) may be reduced. By replacing the second semiconductor layers 108 with a sacrificial dielectric layer 139 prior to formation of epitaxial S/D features 146, there is minimum reaction between the first semiconductor layers 106 and the sacrificial dielectric layer 139 during the subsequent formation of the epitaxial S/D features 146, and the sacrificial dielectric layer 139 can be removed with an enhanced etch selectivity over the first semiconductor layers 106. Since the surface profile of the first semiconductor layers 106 remains substantially intact during the channel formation stage, the channel resistance of the nanosheet channel layers is not increased and the issues discussed herein are avoided.

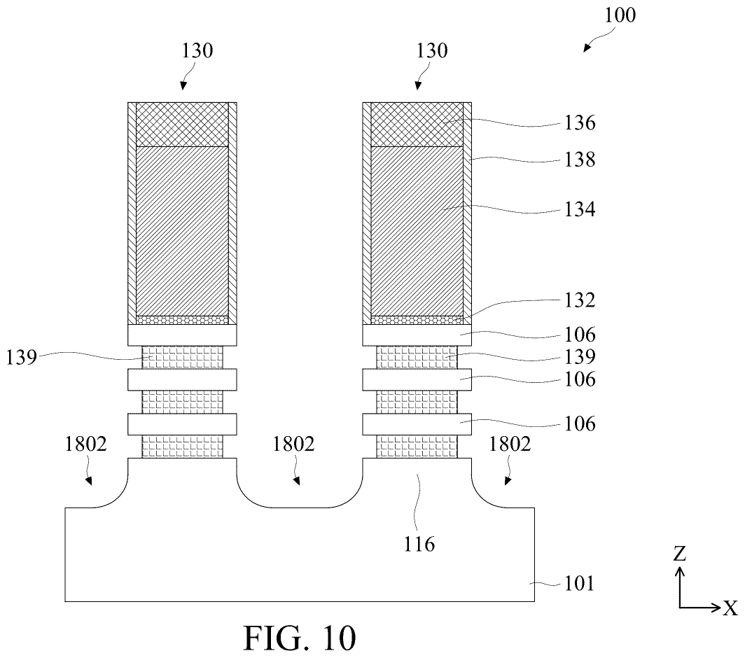

In FIG. 10, an etch back process is performed to remove portions of the sacrificial dielectric layers 139 other than the portions of the sacrificial dielectric layers 139 formed in the openings 137 (FIG. 8). In some embodiments, the etch back process is an anisotropic etching process. The etch back process may be a selective etch process that removes the sacrificial dielectric layers 139 but does not substantially affect the sacrificial gate structures 130, the gate spacers 138, the first semiconductor layers 106, and the substrate 101. The selective etch process is performed until edge portions of each sacrificial dielectric layer 139 between first semiconductor layers 106 are removed. In other words, the majority of the sacrificial dielectric layers 139 between the first semiconductor layers 106 remains after the etch back process.

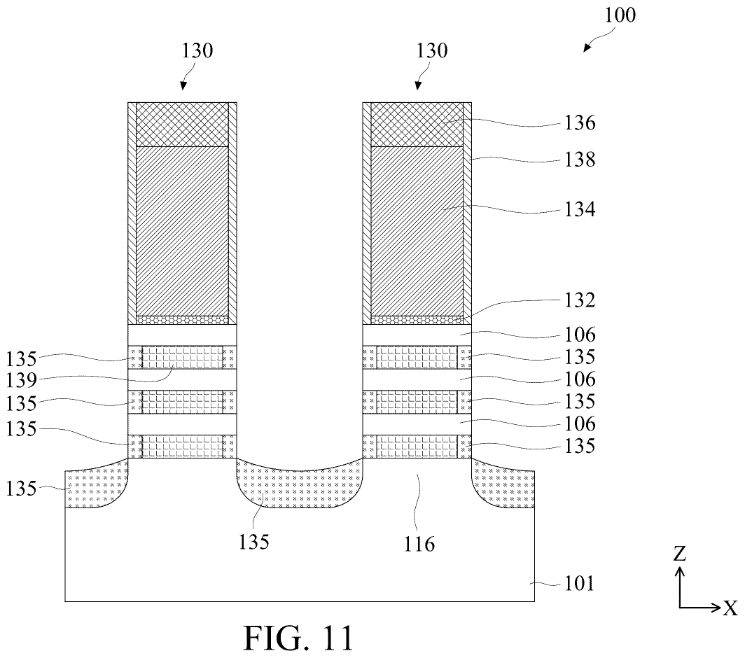

In FIG. 11, after removing edge portions of the sacrificial dielectric material 139, a filling layer 135 is refilled in the region where the sacrificial dielectric layers 139 were removed. The filling layer 135 may be made of a semiconductor material. In one embodiment, the filling layer 135 is formed of silicon germanium (SiGe). In some embodiments, the filling layer 135 is formed of SiGe with an atomic concentration of Ge in a range of about 30 at. % to about 70%. In some embodiments, the filling layer 135 is formed of germanium (e.g., pure Ge). While germanium is discussed, other semiconductor materials may also be used. Suitable materials for the filling layer 135 may include, but are not limited to, gallium (Ga), indium (In), tin (Sn), selenium (Se), antimony (Sb), etc.

The filling layer 135 may be formed using cyclic deposition etch (CDE) epitaxy process, selective epitaxial growth (SEG), ALD, MBE, or any suitable growth process. In cases where CDE epitaxy process is used to form SiGe for the filling layer 135, the deposition process may use one or more etching gases. Suitable etching gases may include, but are not limited to, hydrogen chloride (HCl), a chlorine gas (Cl₂), or the like. The first semiconductor layers 106 and the substrate 101 may be exposed to silicon-containing precursor(s) and germanium-containing precursor(s) in a process chamber for a first period of time to grow SiGe from the first semiconductor layers 106 and the substrate 101, followed by a selective etch where the deposited filling layer 135 (e.g., SiGe) is exposed to etchants (e.g., HCl, etc.) for a second period of time to selectively remove amorphous or polycrystalline portions of the SiGe while leaving crystalline portions of the SiGe intact. The process chamber may be flowed with a purge gas (e.g., N₂) between the epitaxial growth and the selective etch. Due to different growth rates on different surface planes, SiGe is epitaxially grown faster on top and bottom surfaces (e.g., (100) crystal planes) of silicon layers, and slower on sidewalls (e.g., (110) crystal planes) of silicon layers. Therefore, the process conditions of the growth process can be configured in accordance with the crystal planes of the first semiconductor layer 106 and the substrate 101 to promote preferential growth of the filling layer in the region defined by the first semiconductor layers 106 and the sacrificial dielectric layers 139. The epitaxial growth and selective etch of the CDE epitaxy process are repeated until the gaps between two adjacent first semiconductor layers 106 are formed with the filling layer 135.

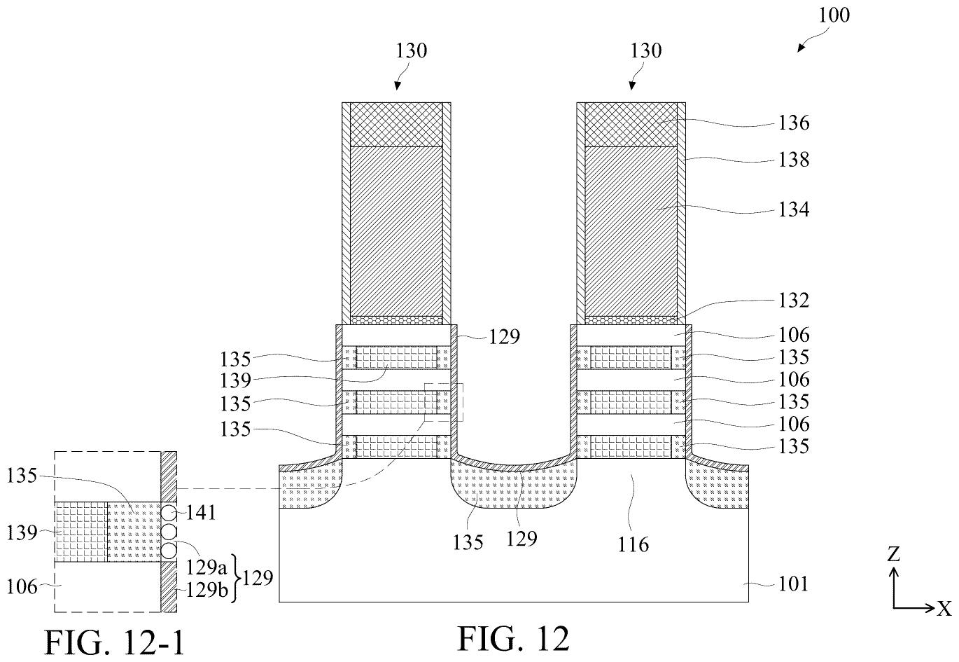

In FIG. 12, an oxide layer 129 is formed on the exposed surfaces of the first semiconductor layers 106 and the filling layers 135. The oxide layer 129 serves as a covering layer. The oxide layers 129 may be formed as a result of a cleaning process and a post-treatment process. The cleaning process may be any suitable wet etch process that transforms surface portions of the first semiconductor layers 106 and the filling layers 135 into an oxide layer. In cases where the first semiconductor layers 106 include Si and the filling layers 135 include SiGe, the oxide layer 129 (e.g., oxide layer 129a, see FIG. 12-1) formed on the surface of the first semiconductor layers 106 may include silicon oxide (SiO) and the oxide layer 129 (e.g., oxide layer 129b, see FIG. 12-1) formed on the surface of the filling layers 135 may include silicon germanium oxide (SiGeO). The post-treatment process may be any suitable etch process that selectively removes Ge from SiGeO. In cases where the filling layers 135 includes SiGe having higher atomic concentration of Ge (e.g., about 30 at. % or greater), the removal of germanium from the oxide layers 129a may result in oxide layers with different porosities and film qualities than the oxide layers 129b that are deposited on the first semiconductor layers 106. For example, the oxide layer 129a on the filling layers 135 may become a porous SiO having a first porosity, and the oxide layer 129b on the first semiconductor layers 106 may have a second porosity less than the first porosity. As will be discussed in more detail below, the greater porosity of the oxide layer 129 allows easy removal of SiGe at a later stage.

The oxide layer 129 may have a thickness in a range between about 5 Å and about 10 Å. If the thickness of the oxide layer 129 is below about 5 Å, the oxide layer 129 may not be thick enough to function as its intended purpose. If the thickness of the oxide layer 129 is greater than about 10 Å, the chemical gas may have trouble passing through at a later stage.

FIG. 12-1 illustrates an enlarged view of a portion of the semiconductor device structure 100 showing the oxide layers 129a on the filling layers 135, in accordance with some embodiments. As can be seen, the oxide layers 129a on the filling layers 135 contain tiny holes or air gaps 141, while the oxide layers 129b on the first semiconductor layers 106 are free of any holes or air gaps.

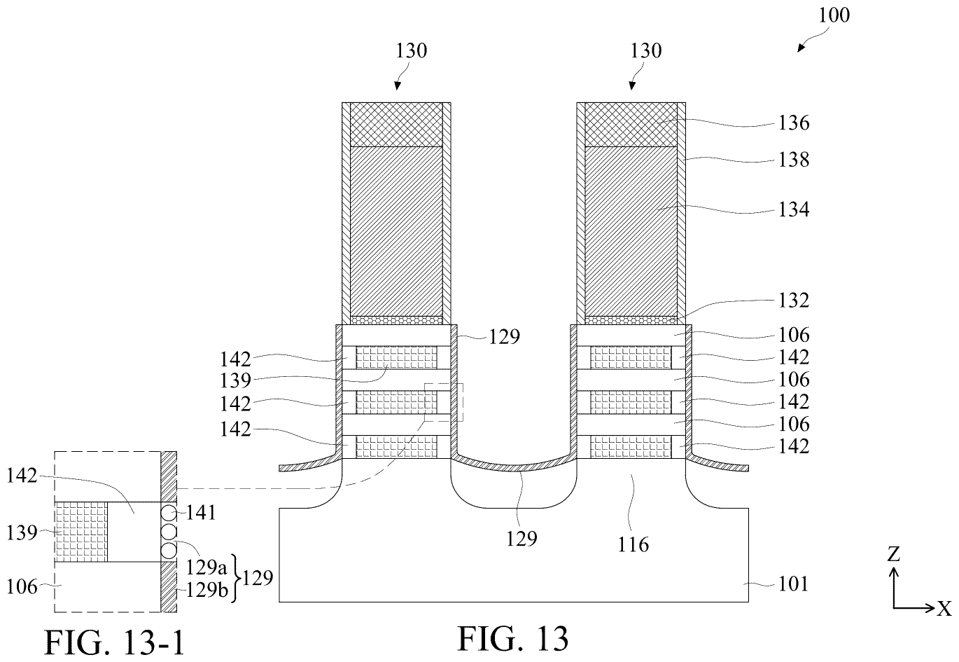

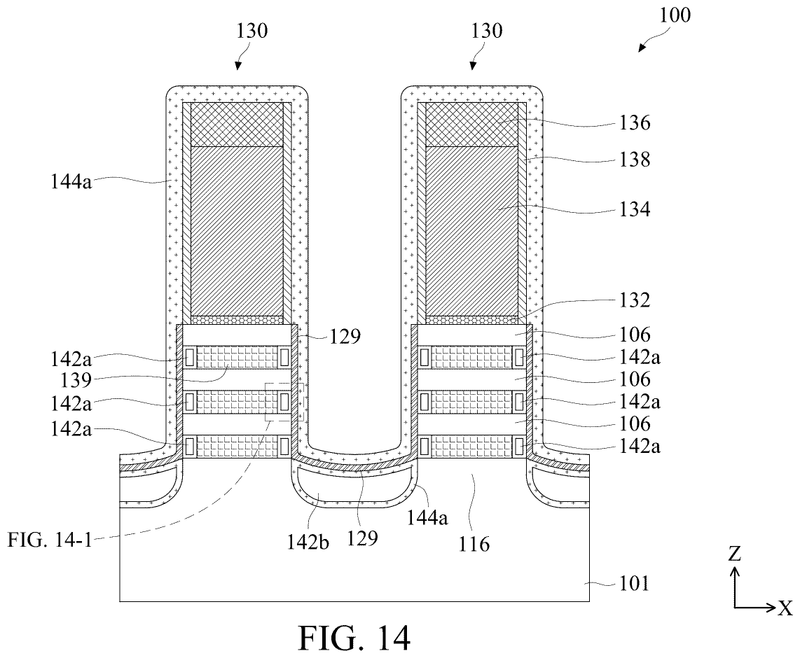

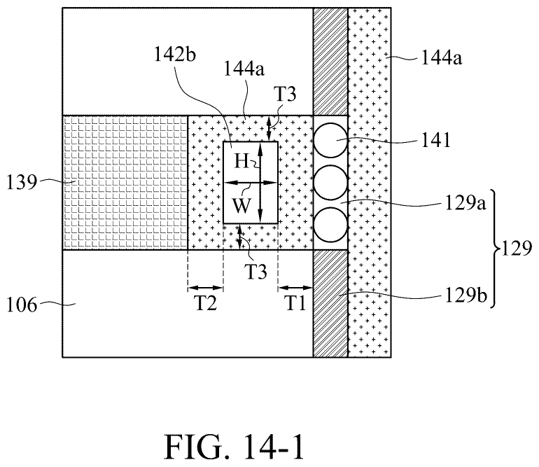

In FIGS. 13 and 14, the filling layers 135 are removed and a dielectric liner layer 144a is deposited on the exposed surfaces of the semiconductor device structure 100 and in the region where the filling layers 135 were removed. The removal of the filling layers 135 forms cavities 142, and may be done by exposing the semiconductor device structure 100 to an etching gas that is adapted to selectively remove SiGe without substantially affecting SiO. Thereafter, the semiconductor device structure 200 is exposed to a deposition gas to form the dielectric liner layer 144a in the region (e.g., cavities 142) formed as a result of removal of the filling layers 135. The dielectric liner layer 144a may be deposited by forming a conformal dielectric layer using a conformal deposition process, such as ALD. The dielectric liner layer 144a is a conformal layer covering the exposed surfaces of the sacrificial gate structures 130, the oxide layers 129, the substrate 101, the first semiconductor layers 106, and the sacrificial dielectric layers 139. The dielectric liner layer 144a and the sacrificial dielectric material 139 include a material chemically different from each other. For example, the dielectric liner layer 144a and the sacrificial dielectric material 139 may include different materials having different etch selectivity. In some embodiments, the dielectric liner layer 144a is a low-K dielectric material, such as SION, SiCN, SiC, SiOC, SiOCN, or SiN.

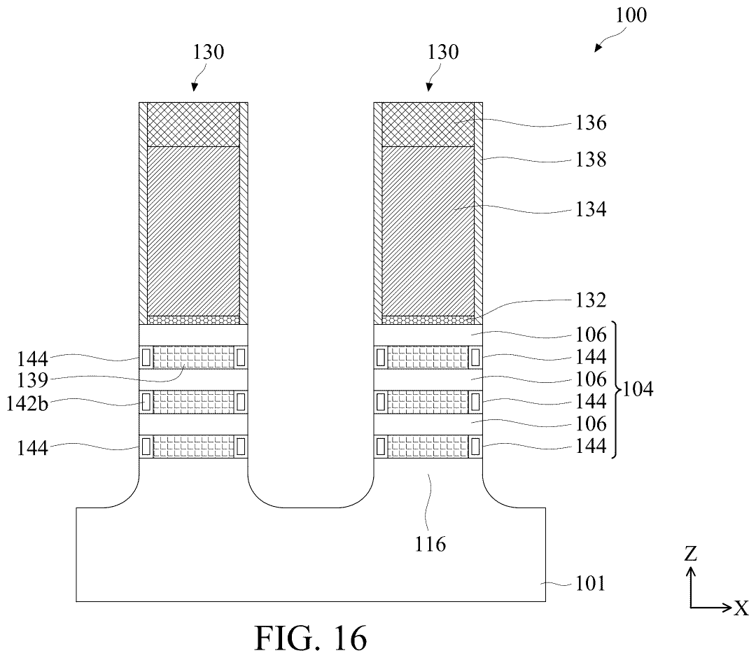

In some embodiments, the dielectric liner layer 144a is deposited on exposed surfaces of the cavities 142 such that an air gap 142a is confined or trapped in each cavity 142 formed as a result of removal of the filling layers 135. That is, the air gaps 142a are formed in the regions defined by the oxide layer 129b, the first semiconductor layer 106, and the sacrificial dielectric layer 139. Likewise, the air gaps 142b are formed in the regions defined by the oxide layer 129 and the substrate 101. The air gaps 142a, 142b are surrounded by the dielectric liner layer 144a, which is to be formed as dielectric spacers 144 (FIG. 16). Comparing to traditional semiconductor device structures using solid dielectric spacers, the formation of the air gaps 142a, 142b allow the subsequent dielectric spacers 144 to be formed with hollow region in the center, which can effectively reduce gate-to-source/drain capacitance of about 3% to about 4% when compared to traditional nanostructures.

Since the oxide layer 129a is porous, the etching gas can easily flow through the oxide layer 129a and remove the filling layers 135 without removing the oxide layer 129a, 129b. It has been observed that the ability for effective removal of the filling layers 135 (e.g., SiGe) is closely related to the porosity of the oxide layer 129a. Therefore, the Ge concentration in the filling layers 135 should be controlled so that the etching gas can pass through the oxide layer 129a without affecting the integrity of the oxide layer 129a. If the Ge at. % is not high enough (e.g., less than about 30 at. %), the porosity of the oxide layer 129a may not be sufficient for easy passage of the chemical gas through the oxide layer 129a, resulting in ineffective removal of the filling layers 135 (e.g., SiGe) and defective formation of the dielectric liner layer 144a. On the other hand, if the Ge at. % is too high (e.g., greater than about 70 at. %), the porosity in the oxide layer 129a may be overwhelming and diminish the mechanical strength of the oxide layer 129a. As a result, the integrity of the oxide layer 129a is impaired during removal of the filling layers 135 and/or formation of the dielectric liner layer 144a.

FIG. 13-1 illustrates an enlarged view of a portion of the semiconductor device structure 100 showing the air gap 142 is formed after removal of the filling layers 135, in accordance with some embodiments.

FIG. 14-1 illustrates an enlarged view of a portion of the semiconductor device structure 100 showing the dielectric liner layer 144a, in accordance with some embodiments. As can be seen, the dielectric liner layer 144a is conformally formed on exposed surfaces of the oxide layer 129 (e.g., oxide layer 129a), the first semiconductor layers 106, and the sacrificial dielectric layer 139, defining the air gap 142b therein. Likewise, the oxide layers 129a on the filling layers 135 contain tiny holes or air gaps 141, while the oxide layers 129b on the first semiconductor layers 106 are free of any holes or air gaps.

The dielectric liner layer 144a may have a thickness in a range of about 0.5 nm to about 10 nm. If the thickness of the dielectric liner layer 144a is below about 0.5 nm, there may be risk associated with penetration of unexpected elements (e.g., dopants, etchant, etc.) through the dielectric liner layer 144a in the subsequent processes. On the other hand, if the thickness of the dielectric liner layer 144a is greater than about 10 nm, the available space for air gaps 142a will be limited, resulting in poor gate-to-S/D features capacitance reduction.

The dielectric liner layer 144a between the oxide layer 129a and the air gap 142b may have a thickness T1, the dielectric layer 144a between the sacrificial dielectric layer 139 and the air gap 142b may have a thickness T2, the dielectric layer 144a between the first semiconductor layer 106 and the air gap 142b may have a thickness T3. In some embodiments, the thickness T1, T2, and T3 is in a range of about 0.5 nm to about 5 nm. In some embodiments, the thickness T1 and the thickness T2 are substantially the same. The air gap 142b may have a width W and a height H, and the width W and the height H may be in a range of about 0.5 nm to about 10 nm.

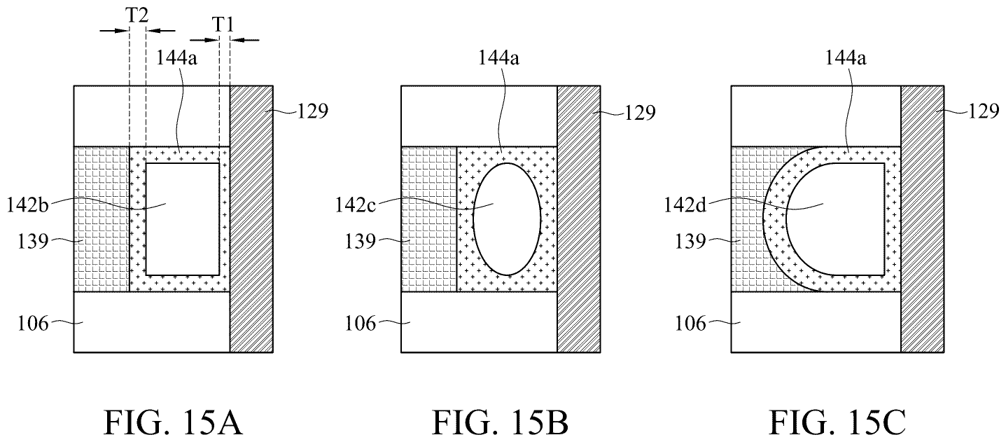

FIGS. 15A, 15B, and 15C are schematic views of the dielectric liner layer 144a showing air gaps with different shapes, in accordance with some embodiments. In FIG. 15A, the air gap 144a has a quadrilateral shape, such as a square or rectangular shape. The dielectric liner layer 144a has a first side in contact with the oxide layer 129 (e.g., oxide layer 129a) and a second side in contact with the sacrificial dielectric layer 139, in which a first portion of the dielectric liner layer 144a contacting the oxide layer 129 has a thickness T1 that is less than a second portion of the dielectric liner layer 144a contacting the sacrificial dielectric layer 139. In FIG. 15B, the dielectric liner layer 144a may be deposited in a similar fashion to the embodiment shown in FIG. 15A except that the air gap 142c has an oval shape. In FIG. 15C, the dielectric liner layer 144a has a first side in contact with the oxide layer 129 (e.g., oxide layer 129a) and a second side in contact with the sacrificial dielectric layer 139, in which a first portion of the dielectric liner layer 144a contacting the oxide layer 129 has a flat profile, and a second portion of the dielectric liner layer 144a contacting the sacrificial dielectric layer 139 has a convex profile, which may occur due to excessive etching of the sacrificial dielectric layer 139 during the removal of the filling layers 135, or consumption by source/drain cleaning or channel formation etch at a later stage.

In FIG. 16, an anisotropic etching is performed to remove portions of the conformal dielectric liner layer 144a other than the dielectric liner layer 144a formed in the cavities 142 (FIG. 13). The dielectric liner layer 144a in the cavities forms dielectric spacers 144, and are protected by the first semiconductor layers 106 during the anisotropic etching process. The sacrificial dielectric layer 139 is capped between the dielectric spacers 144 along the X direction.

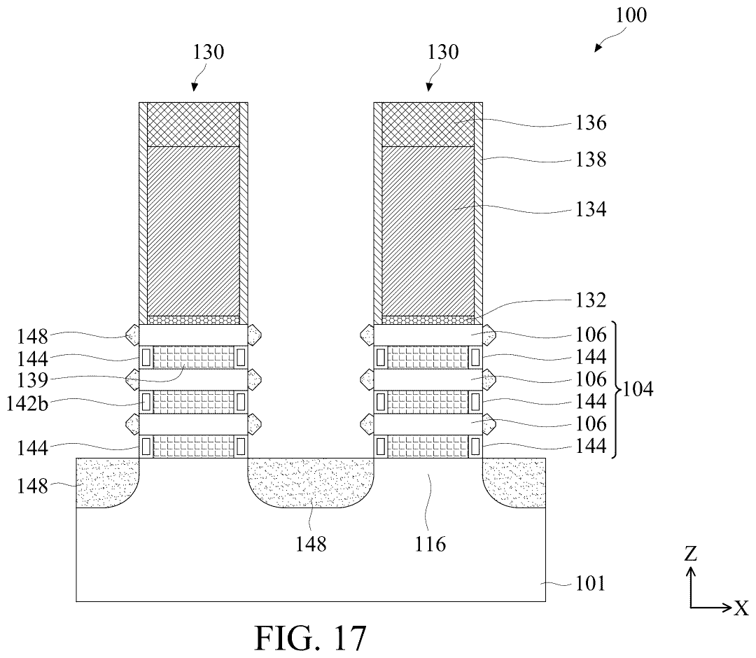

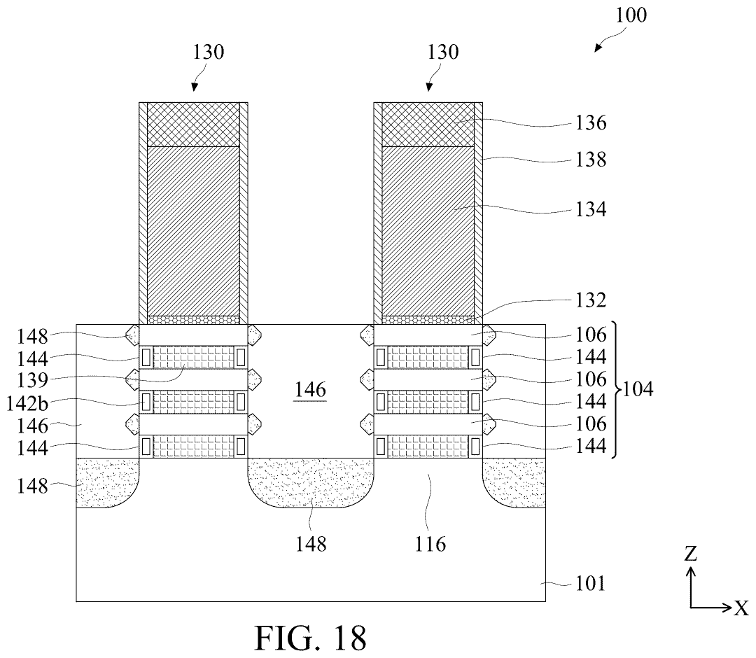

In FIGS. 17 and 18, epitaxial S/D features 146 are formed in the source/drain (S/D) regions. The epitaxial S/D features 146 may grow vertically and horizontally to form facets, which may correspond to crystalline planes of the material used for the first semiconductor layers 106. In some cases, the epitaxial S/D features 146 of a fin structure may grow and merge with the epitaxial S/D features 146 of the neighboring fin structures. In some cases, the epitaxial S/D features 146 are formed with a substantially uniform CD from top to bottom. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The epitaxial S/D features 146 are in contact with the first semiconductor layers 106 and the dielectric spacers 144. The sacrificial dielectric layer 139 under the sacrificial gate structure 130 are separated from the epitaxial S/D features 146 by the dielectric spacers 144.

The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

In some embodiments, after formation of the dielectric spacers 144, a facetted structure 148 is formed on exposed surfaces of the first semiconductor layers 106 and exposed surfaces (e.g., well portion 116) of the substrate 101 to promote epitaxial growth of subsequent S/D features 146. In some embodiments, a portion of the facetted structure 148 may be in further contact with the dielectric spacer 144. The facetted structures 148 may grow both vertically and horizontally to form facets, which may correspond to crystal planes of the material of the first semiconductor layers 106 and exposed surfaces of the substrate 101. Due to different growth rates on different surface planes, facets can be formed. For example, during the growth of the facetted structures 148, the growth rate on (111) planes of the first semiconductor layer 106 (e.g., silicon) may be lower than the growth rate on other planes, such as (110) and (100) planes of the first semiconductor layer 106. Therefore, facets are formed as a result of difference in growth rates of the different planes. In one embodiment, the facetted structures 148 have a rhombus-like shape. Comparing to the exposed surfaces of the first semiconductor layer 106, the facets of the facetted structures 148 provide increased surface area to promote epitaxial growth of the S/D features 146. Once the facetted structures 148 are formed, the S/D features 146 may grow on the facetted structures 148 and cover the exposed surfaces of the facetted structures 148.

In some embodiments, the facetted structures 148 include silicon. In some embodiments, the facetted structures 148 include undoped silicon. In some embodiments, the facetted structures 148 include silicon and n-type or p-type dopants, depending on the conductivity type of the S/D features 146 to be grown thereon. For example, the facetted structure 148 at a n-type device region may be silicon doped with n-type dopants, such as phosphorous or arsenic, and the facetted structure 148 at a p-type device region may be silicon doped with p-type dopants, such as boron. The facet structures 148 may be formed using selective epitaxial growth (SEG), ALD, MBE, or any suitable growth process. In some embodiments, the first semiconductor layers 106 may be exposed to silicon-containing precursor(s) and n-type or p-type dopant-containing precursor(s) in a process chamber to form facetted structure 148. The process conditions of the growth process are configured in accordance with the crystal planes of the first semiconductor layer 106 and the substrate 101 to promote faceting formation of the facetted structures 148. Once the predetermined volume of the facetted structures 148 is reached, the flow of the n-type or p-type dopant-containing precursor(s) may be terminated and group IV or group V precursor(s) are introduced into the process chamber along with the silicon-containing precursor(S) to form the S/D features 146. Therefore, the facetted structures 148 are formed of a material that is chemically different from that of the S/D features 146. The dopants in the S/D features 146 may be added during the formation of the S/D features 146, or after the formation of the S/D features 146 by an implantation process.

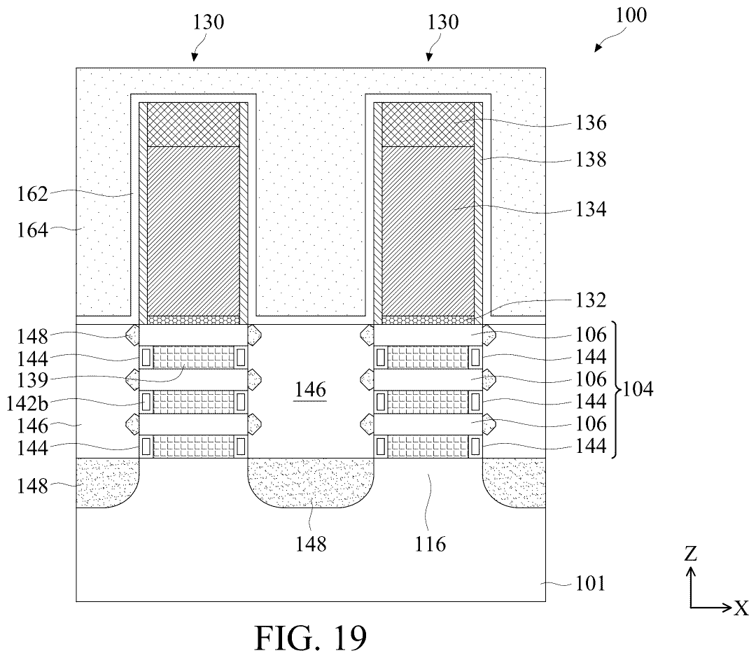

In FIG. 19, a contact etch stop layer (CESL) 162 is conformally formed on the exposed surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164.

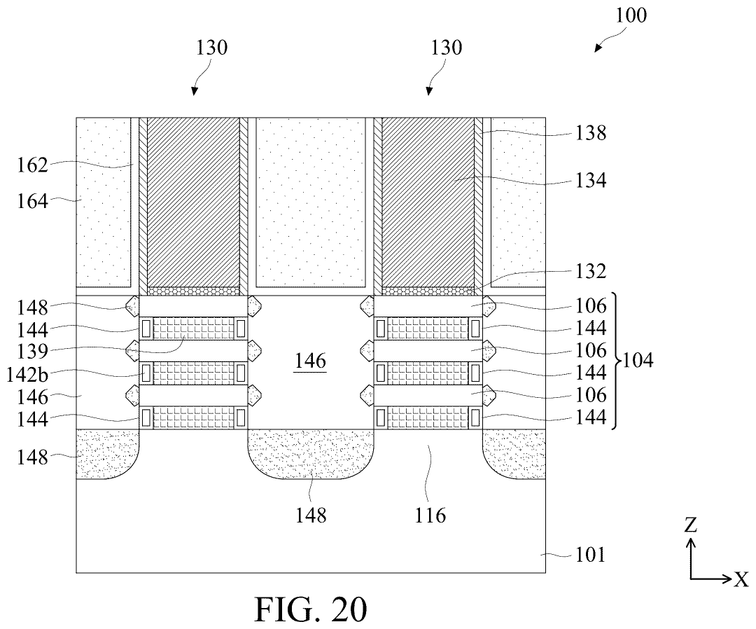

In FIG. 20, after the first ILD layer 164 is formed, a planarization operation, such as CMP, is performed on the semiconductor device structure 100 until the sacrificial gate electrode layer 134 is exposed. The top surfaces of the sacrificial gate electrode layer 134, the gate spacers 138, the CESL 162, and the first ILD layer 164 are substantially co-planar after the CMP.

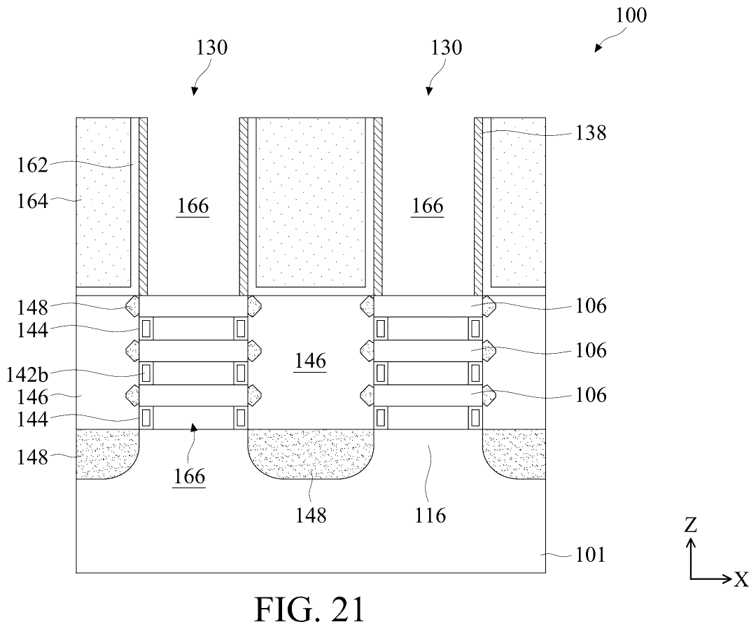

In FIG. 21, the sacrificial gate structures 130, the sacrificial gate dielectric layer 132, and the sacrificial dielectric layers 139 are removed (i.e., channel formation stage). The removal of the sacrificial gate structures 130 and the sacrificial dielectric layers 139 forms an opening 166 between the first semiconductor layers 106. Due to high selectivity between silicon and porous oxide (i.e., sacrificial dielectric layers 139), which is higher than selectivity between silicon and silicon germanium, minimal or no silicon loss would occur during channel formation stage. The sacrificial gate structures 130 can be removed using plasma dry etching and/or wet etching. In some embodiments, a wet etchant such as a tetramethylammonium hydroxide (TMAH) solution can be used to selectively remove the sacrificial dielectric layers 139, the sacrificial gate electrode layer 134, and the sacrificial gate dielectric layer 132 but not the gate spacers 138, the first ILD layer 164, and the CESL 162. After the removal of the sacrificial gate structures 130, the first semiconductor layers 106 and the inner spacers 144 are exposed to the opening 166.

The sacrificial dielectric layers 139 disposed between the first semiconductor layers 106 help preserve the integrity and surface profile of the first semiconductor layers 106 during the channel formation stage since the sacrificial dielectric layers 139 do not react or intermix with the first semiconductor layers 106 in prior high temperature process of the epitaxial S/D features 146. Therefore, the sacrificial dielectric layers 139 can be removed without damaging the first semiconductor layers 106 during the channel formation stage.

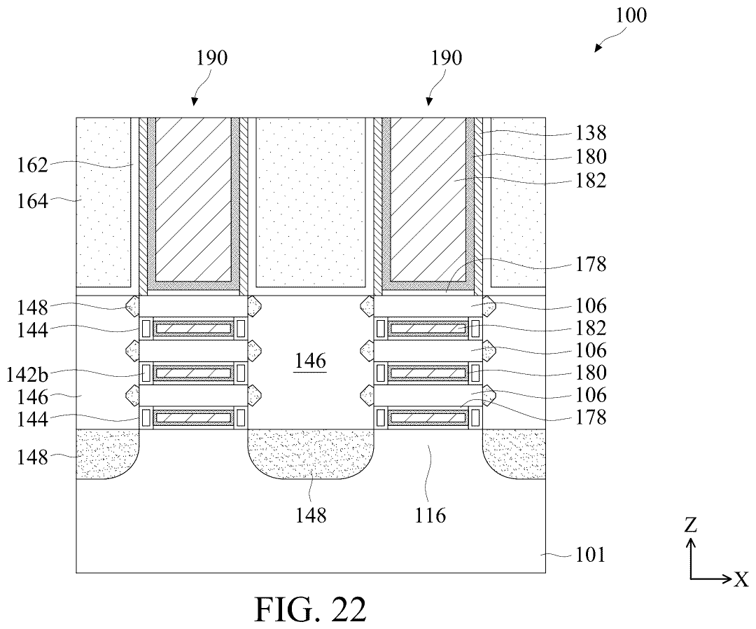

In FIG. 22, replacement gate structures 190 are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178 may also form on the exposed surfaces of the substrate 101. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, and the CESL 162). The gate dielectric layer 180 may be formed of a material chemically different than that of the sacrificial gate dielectric layer 132. The gate dielectric layer 180 may include or made of a high-k dielectric material. The gate dielectric layer 180 may be a conformal layer formed by a conformal process, such as an ALD process, a PECVD process, a molecular-beam deposition (MBD) process, or the like, or a combination thereof.

After formation of the IL 178 and the gate dielectric layer 180, the gate electrode layer 182 is formed on the gate dielectric layer 180. The gate electrode layer 182 filles the openings 166 (FIG. 21) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

As can be seen, a portion of the dielectric layers 144, which are in contact with the IL 178, the gate dielectric layer 180. The gate electrode layer 182 is separated from the dielectric layer 144 by the gate dielectric layer 180. Stated differently, the air gap 142b is separated from the gate electrode layer 182 by the gate dielectric layer 180.

Portions of the gate electrode layer 182, the one or more optional conformal layers (if any), and the gate dielectric layer 180 above the top surfaces of the first ILD layer 164, the CESL 162, and the gate spacers 138 may be removed by a planarization process, such as by a CMP process. After the CMP process, the top surfaces of the first ILD layer 164, the CESL 162, the gate spacers 138, gate dielectric layer 180, and the gate electrode layer 182 are substantially co-planar.

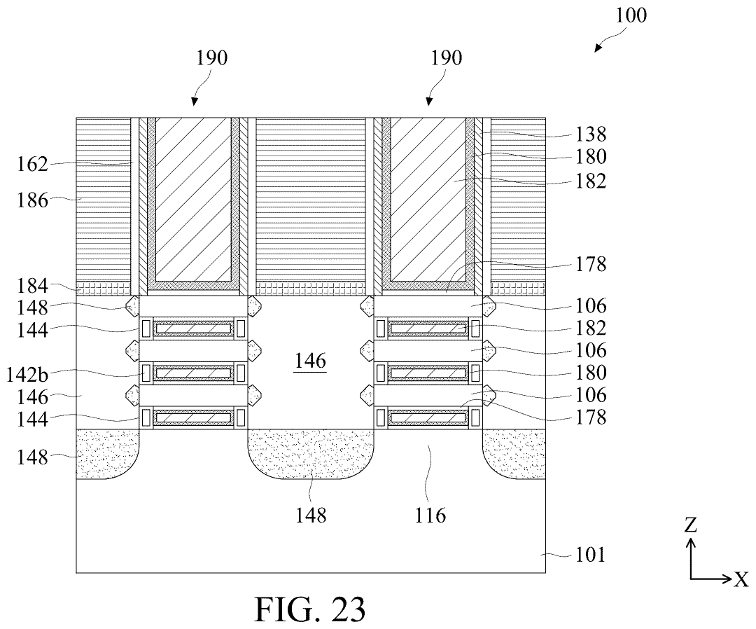

In FIG. 23, contact openings are formed through the first ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. While not shown, a barrier layer (e.g., TiN, TaN, or the like) may be formed on sidewalls of the contact openings prior to forming the S/D contacts 186. The silicide layer 184 conductively couples the epitaxial S/D features 146 to subsequent S/D contacts 186 formed in the contact openings. The silicide layer 184 may include a metal or metal alloy silicide, and the metal includes a noble metal, a refractory metal, a rare earth metal, alloys thereof, or combinations thereof. Then, a planarization process, such as CMP, is performed to remove excess deposition of the contact material and expose the top surface of the gate electrode layer 182.

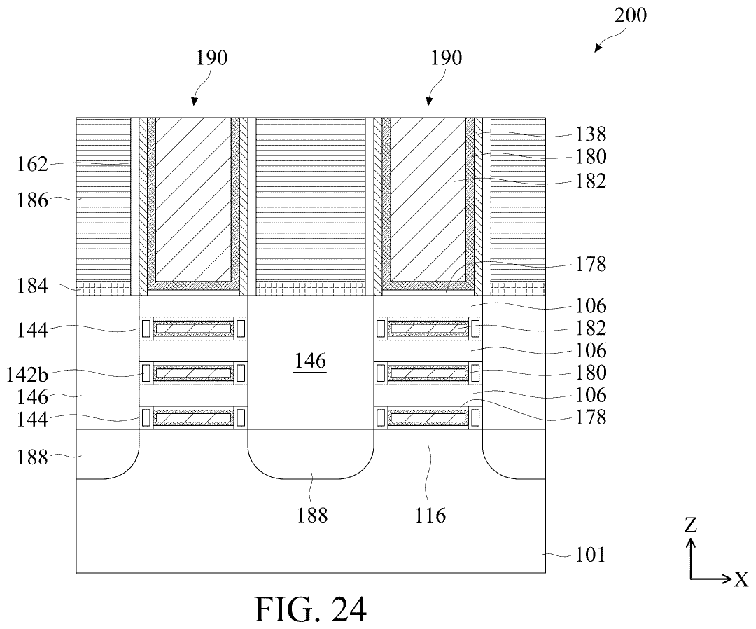

FIG. 24 illustrates a cross-sectional view of a semiconductor device structure 200, in accordance with some alternative embodiments. The semiconductor device structure 200 is substantially identical to the embodiment of FIG. 23 except that a dielectric layer 188 is formed on the exposed surfaces of the substrate 101 prior to formation of the source/drain features 146. The dielectric layer 188 may have a top surface at an elevation that is at or slightly below an interface defined by the dielectric spacer 144 and the substrate 101. The dielectric layer 188 may be made of a dielectric material such as silicon oxide, silicon nitride, silicon carbide, silicon oxynitride, SiCN, silicon oxycarbide, SiCON, and/or combinations thereof. The dielectric layer 188 may be formed by any suitable process, such as CVD, PECVD, electron cyclotron resonance CVD (ECR-CVD), or any suitable deposition technique.

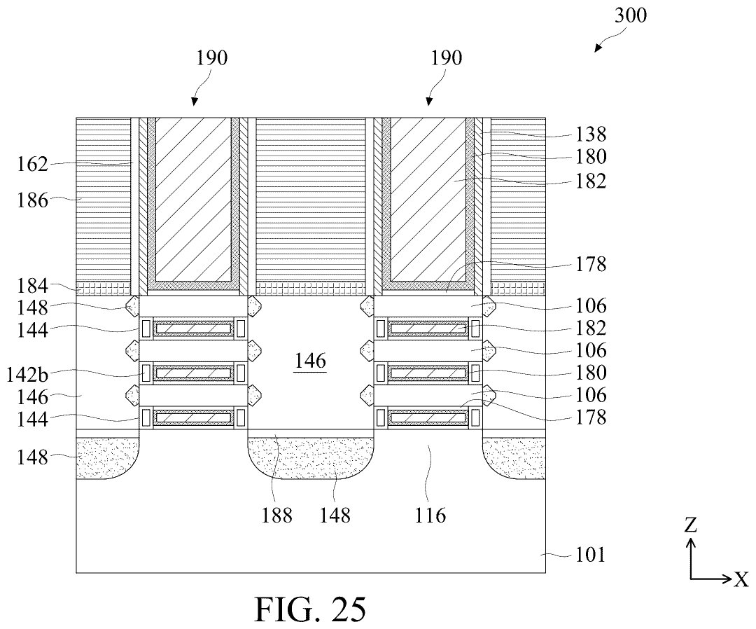

FIG. 25 illustrates a cross-sectional view of a semiconductor device structure 300, in accordance with some alternative embodiments. The semiconductor device structure 300 is substantially identical to the embodiment of FIG. 23 except that a dielectric layer 190 is formed between the source/drain (S/D) feature 146 and the facetted structure 148 on the substrate 101. In some embodiments, the dielectric layer 190 may have a top surface at an elevation that is at or slightly below an interface defined by the dielectric spacer 144 and the substrate 101. The dielectric layer 190 may include the same material as the dielectric layer 188.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Embodiments of the present disclosure provide an improved approach to reduce gate-to-source/drain feature capacitance by forming air gap in dielectric spacers (i.e., inner spacers) between the source/drain features 146 and the gate electrode layers 182. Prior to forming epitaxial S/D features, SiGe layers between Si nanosheet channel layers are replaced with sacrificial dielectric layers. The sacrificial dielectric layers have minimum reaction with the nanosheet channel layers during subsequent high temperature process of epitaxial S/D features and can be easily removed during channel formation process. Since the integrity and surface profile of the nanosheet channel layers are preserved during the channel formation process, a channel resistance between a source feature and a drain feature can be reduced. As a result, the device performance is improved.

An embodiment is a method for forming a semiconductor device structure. The method includes forming a fin over a substrate, wherein the fin comprises first semiconductor layers and second semiconductor layers alternating stacked. The method also includes forming a sacrificial gate structure over the fin, removing portions of the fin not covered by the sacrificial gate structure, replacing the second semiconductor layers with a sacrificial dielectric material, recessing edge portions of the sacrificial dielectric material to form cavities between the first semiconductor layers, forming a dielectric spacer in the cavities by depositing a conformal layer of a dielectric liner layer on exposed surfaces of each cavity, forming source/drain features on opposite sides of the sacrificial gate structure, and replacing the sacrificial gate structure and the sacrificial dielectric material with a gate structure wrapping around the first semiconductor layers.

Another embodiment is a method for forming a semiconductor device structure. The method includes forming a trench between two adjacent fin structures, each fin comprising a plurality of first semiconductor layers and a plurality of second semiconductor layers alternatingly stacked, removing the second semiconductor layers in each fin structure to form first cavities, filling the first cavities with a sacrificial dielectric layer, removing edge portions of each sacrificial dielectric layer to form second cavities, forming the second cavities with a filling layer, forming an oxide layer on exposed surfaces of the filling layer, removing the filling layer through the oxide layer, depositing a dielectric liner layer on exposed surfaces of the second cavities, removing the oxide layer, forming epitaxial source/drain features in the trench, and replacing the sacrificial dielectric layer with a gate structure wrapping around the first semiconductor layers.

A further embodiment is a semiconductor device structure. The semiconductor device structure includes a source/drain feature disposed over a substrate, a plurality of semiconductor layers vertically stacked over the substrate and disposed adjacent to the source/drain feature, a gate electrode layer surrounding a portion of each of the plurality of the semiconductor layers, and a dielectric spacer disposed between two immediately adjacent semiconductor layers, wherein the dielectric spacer comprises an air gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a fin over a substrate, wherein the fin comprises first semiconductor layers and second semiconductor layers alternating stacked;
forming a sacrificial gate structure over the fin;
removing portions of the fin not covered by the sacrificial gate structure;
replacing the second semiconductor layers with a sacrificial dielectric material;
recessing edge portions of the sacrificial dielectric material to form cavities between the first semiconductor layers;
forming a dielectric spacer in the cavities by depositing a conformal layer of a dielectric liner layer on exposed surfaces of each cavity;
forming source/drain features on opposite sides of the sacrificial gate structure; and
replacing the sacrificial gate structure and the sacrificial dielectric material with a gate structure wrapping around the first semiconductor layers.

2. The method of claim 1, wherein the dielectric liner layer is deposited so that an air gap is confined or surrounded by the dielectric liner layer.

3. The method of claim 2, wherein the air gap has a rectangular shape or an oval shape.

4. The method of claim 1, wherein each of the sacrificial dielectric material and the dielectric liner layer includes a material chemically different from each other.

5. The method of claim 1, wherein the dielectric liner layer comprises a first portion having a first thickness and a second portion having a second thickness different than the first thickness.

6. The method of claim 1, wherein the source/drain features are in contact with each of the dielectric spacer and exposed surfaces of the substrate.

7. The method of claim 1, further comprising:
prior to forming the source/drain features, depositing a dielectric layer on exposed surfaces of the substrate.

8. The method of claim 1, further comprising:
prior to forming the source/drain features, forming a facetted structure on exposed surfaces of the first semiconductor layers and the substrate.

9. The method of claim 8, further comprising:
after forming the facetted structure on the substrate, forming a dielectric layer on the facetted structure.

10. A method for forming a semiconductor device structure, comprising:
forming a trench between two adjacent fin structures, each fin comprising a plurality of first semiconductor layers and a plurality of second semiconductor layers alternatingly stacked;
removing the second semiconductor layers in each fin structure to form first cavities;
filling the first cavities with a sacrificial dielectric layer;
removing edge portions of each sacrificial dielectric layer to form second cavities;
forming the second cavities with a filling layer;
forming an oxide layer on exposed surfaces of the filling layer;
removing the filling layer through the oxide layer;
depositing a dielectric liner layer on exposed surfaces of the second cavities;
removing the oxide layer;
forming epitaxial source/drain features in the trench; and
replacing the sacrificial dielectric layer with a gate structure wrapping around the first semiconductor layers.

11. The method of claim 10, wherein the oxide layer is porous.

12. The method of claim 10, wherein the dielectric liner layer is deposited to form an air gap in the second cavities.

13. The method of claim 10, wherein the filling layer is formed of a semiconductor material.

14. The method of claim 13, wherein the filling layer is silicon germanium having an atomic concentration of Ge in a range of about 30 at. % to about 70%.

15. A semiconductor device structure, comprising:
a source/drain feature disposed over a substrate;
a plurality of semiconductor layers vertically stacked over the substrate and disposed adjacent to the source/drain feature;
a gate electrode layer surrounding a portion of each of the plurality of the semiconductor layers; and
a dielectric spacer disposed between two immediately adjacent semiconductor layers, wherein the dielectric spacer comprises an air gap.

16. The semiconductor device structure of claim 15, wherein the dielectric spacer is disposed between the gate electrode layer and the source/drain feature.

17. The semiconductor device structure of claim 15, further comprising:
a gate dielectric layer surrounding the gate electrode layer disposed between the semiconductor layers.

18. The semiconductor device structure of claim 17, wherein the gate dielectric layer is disposed between and in contact with the gate electrode layer and the dielectric spacer.

19. The semiconductor device structure of claim 17, further comprising:
an interfacial layer (IL) disposed between the gate electrode layer and the semiconductor layer.

20. The semiconductor device structure of claim 15, wherein the dielectric spacer comprises a first portion in contact with the source/drain feature and a second portion adjacent to the gate electrode layer, and the first portion has a first thickness and the second portion has a second thickness different than the first thickness.
